(19) United States
(12) Patent Application Publication
(10) Pub. No.: US 2023/0341463 A1
(43) Pub. Date: Oct. 26, 2023

(54) Architecture and Testing for an Integrated Circuit Package

(71) Applicants: Kalyana Ravindra Kantipudi, San Jose, CA (US); Mahesh K. Kumashikar, Bangalore (IN); MD Altaf Hossain, Portland, OR (US); Ankireddy Nalamalpu, Portland, OR (US)

(72) Inventors: Kalyana Ravindra Kantipudi, San Jose, CA (US); Mahesh K. Kumashikar, Bangalore (IN); MD Altaf Hossain, Portland, OR (US); Ankireddy Nalamalpu, Portland, OR (US)

(21) Appl. No.: 18/217,200

(22) Filed: Jun. 30, 2023

(51) Int. Cl. G01R 31/28; G01R 1/04

(52) U.S. Cl. CPC G01R 31/2896; G01R 1/0433

(57) ABSTRACT

Systems and methods are provided to enable efficient testing of an integrated circuit package. Such a system may include an integrated circuit package and a testing device to test a first portion of socket pins of the integrated circuit package corresponding to a first portion of a die area using a socket during a first pass, and test a second portion of socket pins of the integrated circuit package corresponding to a second portion of the die area using the socket during a second pass.

### BACKGROUND

This disclosure relates to an integrated circuit package architecture that enables a socket to be re-used and/or individual dies within an integrated circuit package to be isolated during testing.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

An integrated circuit package may combine multiple individual dies within a single integrated circuit package. To identify defects, faults, or performance issues, the integrated circuit package may undergo testing procedures to ensure functionality and quality of the individual dies within the integrated circuit package. For example, electrical testing may be performed on the integrated circuit package to verify electrical performance and the functionality of the individual dies. However, in some cases, there may be mechanical handler limitations during the testing procedure.

Additionally, it may be difficult to isolate the individual dies from each other when performing testing. Moreover, the difficulty in isolating the individual dies may cause an increase in power consumption when performing testing because each of the individual dies may be powered on simultaneously. Further, if the integrated circuit package is determined to be faulty, the entire integrated circuit package may be replaced with a new integrated circuit package. Replacing and/or discarding the entire integrated circuit package may be costly.

### BRIEF DESCRIPTION OF THE DRAWINGS

Various aspects of this disclosure may be better understood upon reading the following detailed description and upon reference to the drawings in which:

FIG. 1 is a block diagram of a system including an integrated circuit package and a testing device, in accordance with an embodiment of the present disclosure;

FIG. 2 is a block diagram of the system including the integrated circuit package with alternating depopulated dies and the testing device, in accordance with an embodiment of the present disclosure;

FIG. 3 is a side view of the integrated circuit package and a socket, in accordance with an embodiment of the present disclosure;

FIG. 4 is a flow chart of a method for testing the integrated circuit package, in accordance with an embodiment of the present disclosure;

FIG. 5 is a block diagram of an example of rotation of the integrated circuit package of FIG. 1, in accordance with an embodiment of the present disclosure;

FIG. 6 is a flow chart of a method for isolating each die of the integrated circuit package of FIG. 2 during testing, in accordance with an embodiment of the present disclosure;

FIG. 7 is a block diagram of an example of the integrated circuit package of FIG. 2 in which alternating dies are isolated, in accordance with an embodiment of the present disclosure;

FIG. 8 is a flow chart of a method for identifying each die with a defect of the integrated circuit package, in accordance with an embodiment of the present disclosure; and

FIG. 9 is a block diagram of a data processing system that may incorporate the integrated circuit package, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Embodiments of the present disclosure are directed to the manufacture of an integrated circuit package and isolation of individual dies during testing of the integrated circuit package. The integrated circuit package may be manufactured with a particular design (e.g., a pin map), which may enable a socket to be reused for a multi-pass (e.g., multi-period) insertion test by rotating the integrated circuit package (e.g., rotate 180 degrees) at each insertion. In some embodiments, socket pins of alternating dies in the integrated circuit package may be depopulated (e.g., disconnected or removed from a testing socket). The depopulation of socket pins of each of the alternating dies of the integrated circuit package may enable isolation during testing, where the die with socket pins may be fully tested, along with interface to an adjacent depopulated die.

For example, during a first pass of the multi-pass insertion test, a first portion of each die of the alternating dies may be tested and provided isolated power. During a second pass, a second portion of each die of the alternating dies may be tested and provided isolated power. A first response from the first portion and a second response from the second portion may be analyzed to determine if there is a defect in any number of the dies of the integrated circuit package. Each die with a defect may be individually powered down and be non-functional, while functional non-defective dies may remain for use.

As such, the disclosed manufacture of the integrated circuit package and isolation during testing of the integrated circuit package may enable a reduction in power consumption and increase cost-savings. The isolation of the dies may reduce power consumption because only portions of the integrated circuit package are powered on in the multi-pass test. Further, the increase in cost-savings may occur because individually powering down a die with a defect may still enable the use of the functional dies of the integrated circuit package.

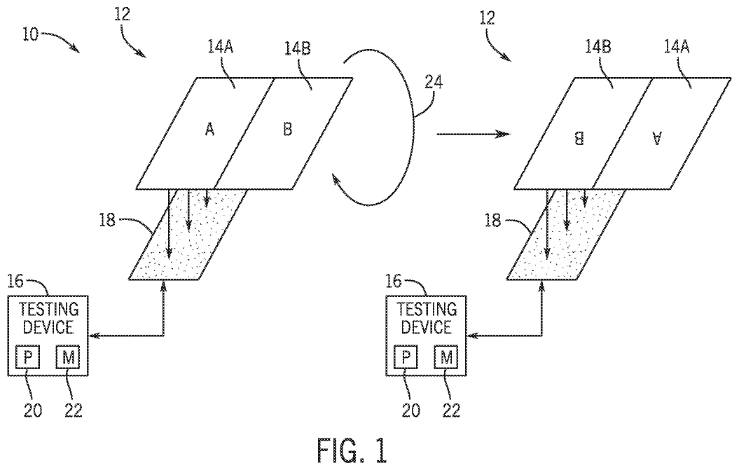

With the foregoing in mind, FIG. 1 is a block diagram of a system 10, including an integrated circuit package 12, a socket 18, and a testing device 16. Further, the integrated circuit package 12 may include a first portion 14A, and a second portion 14B. The integrated circuit package 12 may include multiple individual dies (also sometimes referred to as individual chips) within a single integrated circuit package. In some cases, different dies may enable specific functionality (e.g., processing, data storage, communication, and the like), while in other cases, some of the different dies may have the same functionality. The integrated circuit package 12 may facilitate communication and interconnectivity between the individual dies via die-to-die interfaces. It should be noted that the first portion 14A and the second portion 14B may each include any number of individual dies within the first portion 14A and the second portion 14B.

The testing device 16 may be any suitable computing device and may include a processor 20 and a memory 22. The processor 20 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. In some embodiments, the processor 20 may include one or more application processors and may perform the various functions described herein. The processor 20 may be operably coupled with the memory 22 to execute code and/or other processor-executable instructions. Such programs or instructions executed by the processor 20 may be stored in any suitable article of manufacture that includes one or more tangible, computer-readable media at least collectively storing the instructions or routines, such as the memory 22. The memory 22 may include any suitable article of manufacture for storing data and executable instructions, such as random-access memory, read-only memory, rewritable flash memory, hard drives, and optical discs. Further, in some embodiments, the memory 22 may store instructions (e.g., computer code) executable by the processor 20.

The testing device 16 may enable testing of the functionality, performance, and/or quality of each die within the first portion 14A and/or the second portion 14B. That is, the testing device 16 may check various parameters of each individual die, such as timing, voltage levels, current compensation, signal integrity, or any other suitable parameter. Moreover, the testing device 16 may be communicatively coupled to the socket 18, which may provide connectivity between the testing device 16 and the integrated circuit package 12.

The socket 18 may enable the transfer of power, signals, and/or data between the testing device 16 and the integrated circuit package 12. Further, the socket 18 may include pins that may match the pin configuration of all or the portion (e.g., the first portion, the second portion, or any other portion the integrated circuit package 12 may include) of the integrated circuit package 12. The integrated circuit package 12 may be placed on the socket 18 to create a temporary connection and enable the testing by the testing device 16. Further, after the testing is performed, the integrated circuit package 12 may be removed from the socket. The socket 18 may be any suitable dimension (e.g., length, width, height) to accommodate the integrated circuit package 12 and/or portions of the integrated circuit package 12. As illustrated in FIG. 1, the socket 18 may accommodate the first portion 14A or the second portion 14B separately. As another example, the integrated circuit package 12 may be divided into four or more portions. Thus, the dimensions of the socket 18 may be such that different portions of the integrated circuit package 12 may be similarly separately accommodated. That is, in an embodiment, the socket 18 may be smaller than the size of the integrated circuit package 12. In another embodiment, the socket 18 may be equal in size to the integrated circuit package 12. In yet another embodiment, the socket 18 may be a larger size than the integrated circuit package 12.

Additionally, a pin configuration (e.g., a pin map) of the integrated circuit package 12 may enable the connection of each individual die to external circuitry, such as the socket 18. The pin configuration of the first portion 14A and the second portion 14B may be functionally compatible and may enable a multi-pass insertion test to be performed. That is, each of the pin configurations of the first portion 14A and a rotated second portion 14B may be compatible and tested using the socket 18 at a separate time. As illustrated, in a first pass (e.g., a first stage, a first period) of the multi-pass insertion test, the first portion 14A may be placed on the socket 18, tested, and removed from the socket 18. The integrated circuit package 12 may then undergo a rotation 24 (e.g., rotate 180 degrees). In a second pass (e.g., a second stage, a second period) of the multi-pass insertion test, the second portion 14B may be placed on the socket 18, tested, and removed from the socket 18. In this manner, the first portion 14A and the second portion 14B may be tested by placing the integrated circuit package 12 on the socket 18 in different positions and thus using the same socket 18 in the multi-pass insertion test. It should be noted that, although the integrated circuit package 12 is described as including the first portion 14A and the second portion 14B, the integrated circuit package 12 may include any number of portions. In some embodiments, the number of portions may be proportional to (e.g., equal to, an integer multiple of) the number of passes performed in the multi-pass insertion test.

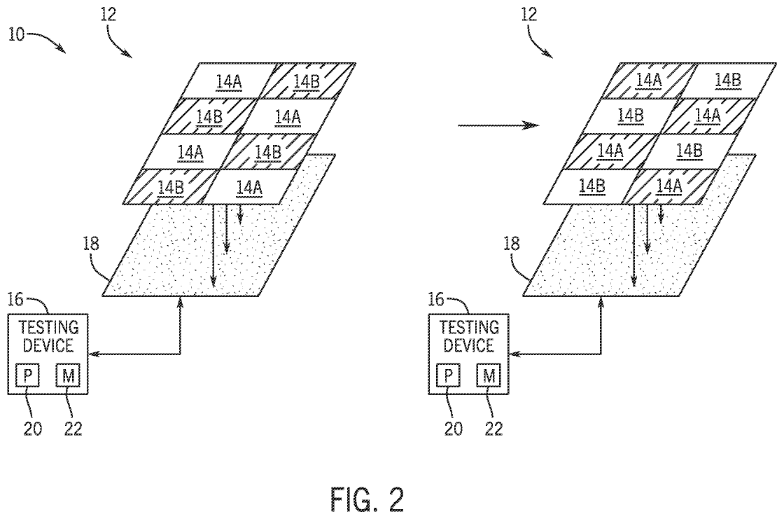

FIG. 2 is a block diagram of another example of the system 10, including the integrated circuit package 12 with alternating depopulated dies, the testing device 16, and the socket 18. As illustrated, the integrated circuit package 12 may be manufactured with the pin configuration to enable the depopulation of alternate pins of each of the individual dies. In this manner, as illustrated, the integrated circuit package 12 may include the first portion 14A, and the second portion 14B, where each adjacent alternating die is depopulated. Further, the first portion 14A or the second portion 14B may be depopulated during each pass insertion (during an associated time period) test using the testing device 16 and socket pins.

As described above, the socket 18 may be any suitable dimension to accommodate the integrated circuit package 12. Moreover, the testing device 16 may enable testing of the functionality, performance, and/or quality of the dies. The pins of the socket 18 may be depopulated to enable the isolation of the dies of the integrated circuit package 12. Thus, as illustrated in FIG. 2, the integrated circuit package 12 may fit and be placed on the socket 18. In the first pass of the multi-pass insertion test, the pin configuration of the first portion 14A may be compatible with the socket 18. Thus, the alternating dies of the first portion 14A may be tested and isolated from the depopulated dies of the second portion 14B. That is, the testing device 16 may test the socket pins of the first portion 14A using the socket 18, which may correspond to a portion of die area of the integrated circuit package 12. Therefore, the power supplied to each die of the first portion 14A may remain localized in each die of the first portion 14A.

In the second pass of the multi-pass insertion test, the pin configuration of the second portion 14B may be compatible with the socket 18. Thus, during testing, the die-to-die interface between each die may be power isolated and not shared with other die interfaces. That is, the testing device 16 may test the socket pins of the second portion 14B using the socket 18, which may correspond to another portion of the die area of the integrated circuit package 12. Thus, the alternating dies of the second portion 14B may be tested and isolated from the depopulated dies of the first portion 14A.

In this manner, the testing device 16 may receive a response (e.g., a first response and a second response) from each of the isolated dies tested during the first pass and the second pass of the multi-pass insertion test. Further, the testing device 16 may analyze the first response from each die of the first portion 14A and the second response from each of the dies of the second portion 14B and determine if each die is working correctly. Each die determined to have a defect (e.g., not working correctly) may be individually powered down from the integrated circuit package 12.

In some embodiments, the socket 18 may be too small to place the first portion 14A and the second portion 14B on the socket simultaneously. Thus, the integrated circuit package 12 may be partially placed on the socket 18. That is, only a portion of the integrated circuit package 12 may be positioned on the socket 18. In this manner, the integrated circuit package 12 may be positioned and/or rotated on the socket 18 to test any number of portions of the integrated circuit package 12. Further, in some embodiments, the integrated circuit package 12 may be placed on the socket and adjacent dies may be tested simultaneously. For example, the alternating dies may alternate in groups of two for the first portion 14A and the second portion 14B. Indeed, two dies of the first portion 14A may be adjacent and tested simultaneously. Further, two dies of the second portion 14B may be adjacent to each other, and alternating with the two dies of the first portion 14A. In this manner, the alternating dies of the first portion 14A and the second portion 14B may be isolated in groups of two. It should be noted that although a group of two dies is described, any number of dies may be included in each group and may be alternated during testing.

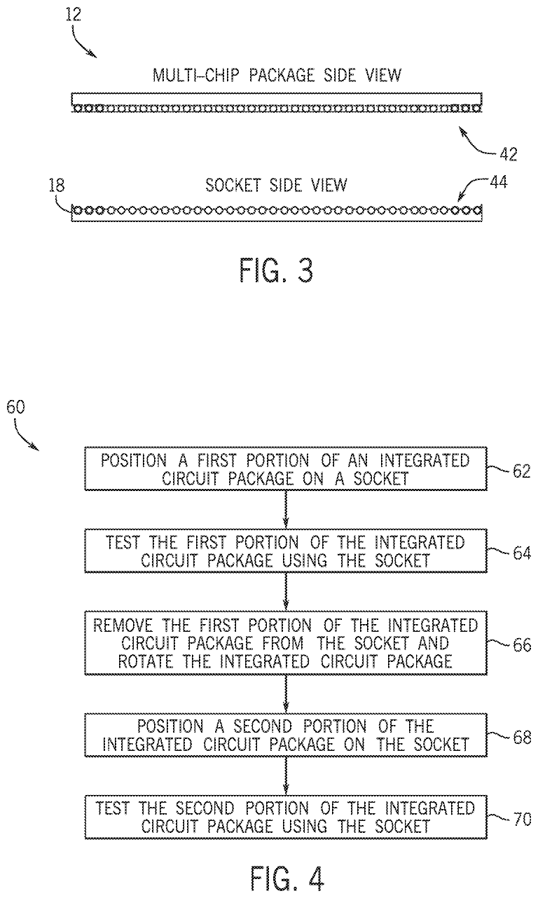

FIG. 3 is a side view of the integrated circuit package 12 and the socket 18. As shown, the integrated circuit package 12 and the socket 18 may each include pads (e.g., 42 and 44). The pads 42 of the integrated circuit package 12 and the pads 44 of the socket 18 may include conductive surfaces to enable electrical connections between the integrated circuit package 12 and the socket 18. In some embodiments, the pads 42 of the integrated circuit package 12 and/or the pads 44 of the socket 18 may be designed to receive the pins of the integrated circuit package 12.

FIG. 4 is a flow chart of a method 60 for testing the integrated circuit package 12 described above in FIG. 1. As disclosed herein, the pin configuration of the first portion 14A and the second portion 14B may be functionally compatible to enable the socket 18 to be used by the first portion 14A and the second portion 14B during the testing of the integrated circuit package 12. With the foregoing in mind, at block 62, the first portion 14A of the integrated circuit package 12 may be positioned on the socket 18. At block 64, the testing device 16 may perform testing of the first portion 14A of the integrated circuit package 12 using the socket 18. After the first portion 14A is tested, at block 66, the first portion 14A of the integrated circuit package 12 may be removed from the socket 18, and the integrated circuit package 12 may undergo the rotation 24. At block 68, the second portion 14B may be positioned on the socket 18. Further, at block 70, the testing device 16 may perform testing of the second portion 14B of the integrated circuit package 12.

In this manner, testing portions (e.g., the first portion 14A, the second portion 14B, or other portions that the integrated circuit package 12 may include) of the integrated circuit package 12 at separate times may enable increasingly larger integrated circuit packages to be tested without overburdening the testing device 16 or a signal carrier (e.g., a cable) of the testing device 16.

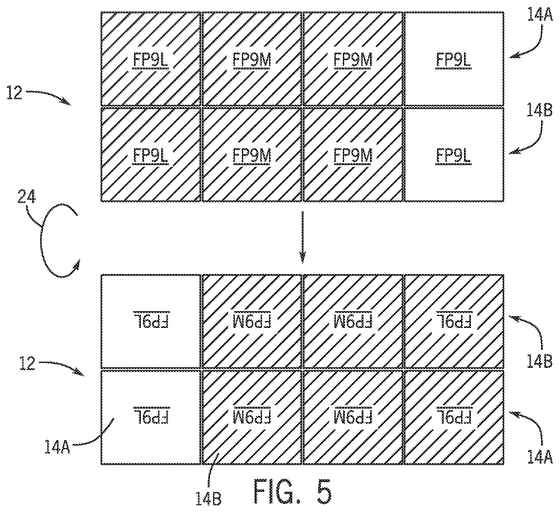

Additionally, FIG. 5 illustrates the rotation 24 of the integrated circuit package 12. For example, as shown in FIG. 5, the first portion 14A of the integrated circuit package 12 may be placed on the socket 18 and tested in a first orientation. Subsequently, the integrated circuit package 12 may undergo the rotation 24, where the rotation 24 may be 180 degrees. Thus, the second portion 14B may be placed on the socket 18 and tested after the rotation 24 of the integrated circuit package 12.

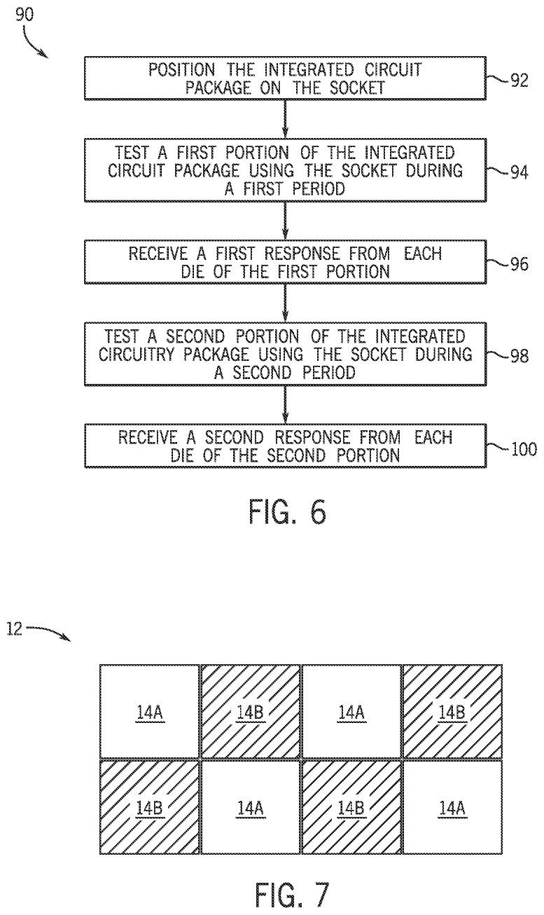

FIG. 6 is a flow chart of a method 90 for isolating each die of the integrated circuit package 12 of FIG. 2 during testing (e.g., the multi-pass insertion test). As disclosed herein, the pin configuration of the first portion 14A and the second portion 14B may be such that alternate pins of each individual die of the socket 18 are depopulated. For example, the depopulated pins of the socket 18 may enable isolation during testing. Thus, at block 92, the integrated circuit package 12 may be positioned on the socket 18. Further, at block 94, the testing device 16 may test the first portion 14A of the integrated circuit package 12 using the socket 18 during a first period.

After testing the integrated circuit package 12, at block 96, the testing device 16 may receive a first response from each die of the first portion 14A. That is, the testing device 16 may receive data and/or an output signal indicative of the functionality of each die of the integrated circuit package 12. For example, the testing device 16 may receive numerical data as the first response, such as measured electrical parameters (e.g., voltage levels, current values, frequency, timing characteristics, and so on). As another example, the first response may include digital signals or data, such as binary values or digital codes indicating the state of various inputs, outputs, or internal nodes of the die of the integrated circuit package 12. It should be noted that the first response may also include any suitable response the testing device 16 may receive when testing the integrated circuit package 12.

The integrated circuit package 12 may then be removed from the socket 18, rotated, and placed on the socket 18 again. At block 98, the testing device 16 may test the second portion 14B of the integrated circuit package 12 using the socket 18 during a second period. At block 100, the testing device 16 may receive a second response from each die of the second portion 14B. The second response may include any suitable response as described above with respect to the first response.

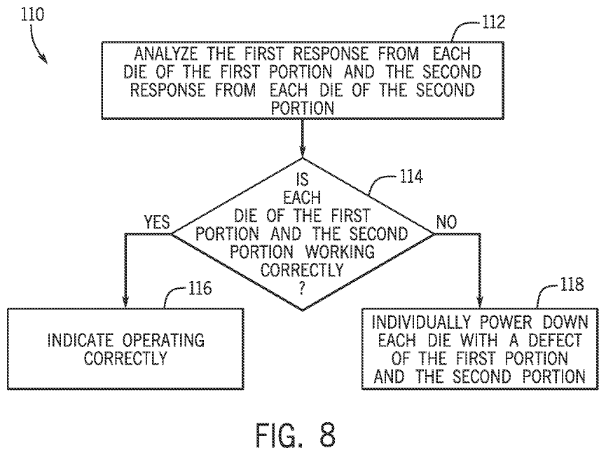

FIG. 7 is a block diagram of an example of the integrated circuit package of FIG. 2 in which each of the alternating dies is isolated by depopulating the pins of the socket 18. As illustrated, the first portion 14A of the pins of the socket 18 may be populated, while the pins of the socket 18 of the second portion 14B may be depopulated. In this manner, each die of the first portion 14A and the second portion 14B may be isolated while being tested by the testing device 16. It should be noted that although eight dies are illustrated in FIG. 8, the integrated circuit package 12 may include any number of dies, including the alternating depopulated dies.

During the first period (e.g., the first pass), the first portion 14A may be tested by the testing device 16. As described herein, the integrated circuit package 12 may then be removed from the socket 18, rotated, and positioned on the socket 18. The second portion 14B of the integrated circuit package 12, may be tested during the second period (e.g., the second pass).

As illustrated, the testing signals used (e.g., sent) in testing the first portion 14A and/or the second portion 14B may remain within each isolated die. In this manner, each die of the first portion 14A and the second portion 14B may remain isolated from each adjacent die. Each die of the first portion 14A and the second portion 14B may remain power isolated and/or signal isolated from each adjacent die. Thus, the multi-pass insertion test may enable a small portion of the dies to be tested within the integrated circuit package 12 without involving full power to the entire integrated circuit package 12.

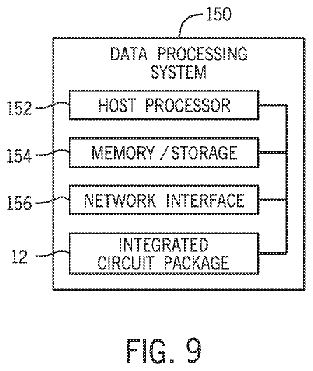

FIG. 9 is a flow chart of a method 110 for identifying each die with a defect of the integrated circuit package 12. As described herein, the testing device 16 may receive the first response from testing the first portion 14A of socket pins of the integrated circuit package 12 corresponding to the portion of the die area and the second response from testing the second portion 14B of socket pins of the integrated circuit package 12 corresponding to another portion of the die area. At block 112, the testing device 16 may analyze the first response from each die of the first portion 14A and the second response from each die of the second portion 14B.

At block 114, the testing device 16 may determine if each die of the first portion 14A and/or each die of the second portion 14B are working correctly. For example, if the testing device 16 receives numerical data (e.g., a first set of numerical data from the first response and a second set of numerical data from the second response) associated with each die, the testing device may compare the numerical data against predetermined limits (e.g., a predetermined set of data) or specifications to assess the performance of each die. As another example, the testing device 16 may receive the digital signals or data (e.g., binary values or digital codes) and compare the response to expected digital patterns to determine if each die is working correctly. In some embodiments, the testing device 16 may receive no response or an invalid response from a particular die of each die, which may also indicate each die that is unable to output the response is not functional.

If each die is determined to be operating correctly, then the method 110 may proceed to block 116. At block 116, the testing device 16 may indicate that each die is operating correctly. Thus, the integrated circuit package 12 may be fully ready for use and implementation by a user. With the foregoing in mind and referring back to block 114, if each die of the first portion 14A and each die of the second portion 14B is not working correctly, then the method 110 may proceed to block 118. At block 118, the testing device 16 may individually power down each die with a defect of the first portion 14A and the second portion 14B. That is, each die with the defect may be powered down while the remaining functional dies may remain operational. In this manner, the integrated circuit package 12 may still be distributed to and implemented by the user. Therefore, the integrated circuit package 12 may continue to operate with the functional dies without individually removing each die with the defect or discarding the integrated circuit package 12.

In some embodiments, package balls of the integrated circuit package 12 may be depopulated based on partial functionality of the integrated circuit package 12. Additionally, in some embodiments, the depopulation of the package balls of the integrated circuit package 12, which are non-functional, may provide additional benefits for use in products.

As such, due to testing a portion of the integrated circuit package 12 at separate times, fewer test signals may be implemented at a single time period. Moreover, increasingly larger integrated circuit packages may be tested without overburdening the testing device 16 or a signal carrier (e.g., a cable) of the testing device 16. Testing the integrated circuit package 12 using the socket 18 may also reduce power consumption and aid in reducing mechanical handler limitations. Additionally, individually powering down a die of the individual dies of the integrated circuit package 12 with the defect may enable the integrated circuit package 12 to still be used, further improving device manufacturing yield.

Bearing the foregoing in mind, the integrated circuit package 12 may be a component included in a data processing system, such as a data processing system 150, shown in FIG. 9. The data processing system 150 may include the integrated circuit package 12 (e.g., a programmable logic device), a host processor 152 (e.g., a processor), memory and/or storage circuitry 154, and a network interface 156. The data processing system 150 may include more or fewer components (e.g., electronic display, user interface structures, application specific integrated circuits (ASICs)). Moreover, any of the circuit components depicted in FIG. 9 may include integrated circuits (e.g., integrated circuit package 12). The host processor 152 may include any of the foregoing processors that may manage a data processing request for the data processing system 150 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 154 may include random access memory (RAM), read-only memory (ROM), one or more hard drives, flash memory, or the like. The memory and/or storage circuitry 154 may hold data to be processed by the data processing system 150. In some cases, the memory and/or storage circuitry 154 may also store configuration programs (bitstreams) for programming the integrated circuit package 12. The network interface 156 may allow the data processing system 150 to communicate with other electronic devices. The data processing system 150 may include several different packages or may be contained within a single package on a single package substrate. For example, components of the data processing system 150 may be located on several different packages at one location (e.g., a data center) or multiple locations. For instance, components of the data processing system 150 may be located in separate geographic locations or areas, such as cities, states, or countries.

In one example, the data processing system 150 may be part of a data center that processes a variety of different requests. For instance, the data processing system 150 may receive a data processing request via the network interface 156 to perform encryption, decryption, machine learning, video processing, voice recognition, image recognition, data compression, database search ranking, bioinformatics, network security pattern identification, spatial navigation, digital signal processing, or some other specialized task.

The techniques and methods described herein may be applied with any suitable type of integrated circuit system. For example, the programmable routing bridge described herein may be used with central processing units (CPUs), graphics processing units (GPUs), graphics cards, hard drives, memory devices, application specific integrated circuits (ASICs), or other electronic components.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. A system comprising:
an integrated circuit package; and
a testing device to:
   test a first portion of socket pins of the integrated circuit package corresponding to a first portion of a die area using a socket during a first pass; and
   test a second portion of socket pins of the integrated circuit package corresponding to a second portion of the die area using the socket during a second pass.

EXAMPLE EMBODIMENT 2. The system of example embodiment 1, wherein the socket is too small for both the first portion and the second portion to be positioned on the socket at the same time.

EXAMPLE EMBODIMENT 3. The system of example embodiment 1, wherein testing the second portion comprises rotating the integrated circuit package before positioning the second portion on the socket.

EXAMPLE EMBODIMENT 4. The system of example embodiment 3, wherein rotating the integrated circuit package comprises a rotation of 180 degrees.

EXAMPLE EMBODIMENT 5. The system of example embodiment 4, wherein the first portion of the integrated circuit package comprises a pin configuration and the rotated second portion also comprises the pin configuration.

EXAMPLE EMBODIMENT 6. The system of example embodiment 1, wherein the second portion does not receive any signals from the testing device during the first pass and the first portion does not receive any signals from the testing device during the second pass.

EXAMPLE EMBODIMENT 7. The system of example embodiment 1, wherein the first portion comprises at least a first die and the second portion comprises at least a second die of the integrated circuit package.

EXAMPLE EMBODIMENT 8. The system of example embodiment 7, wherein the testing device is to test various parameters associated with each die.

EXAMPLE EMBODIMENT 9. The system of example embodiment 8, wherein the various parameters comprise timing, voltage levels, current compensation, signal integrity, or any combination thereof.

EXAMPLE EMBODIMENT 10. The system of example embodiment 1, wherein the first portion is isolated from the second portion during the test of the first portion and the test of the second portion.

EXAMPLE EMBODIMENT 11. A method comprising:
positioning an integrated circuit package in a first position on a socket;
testing a first portion of the integrated circuit package using the socket during a first period;
receiving a first response from at least one die of the first portion;
rotating the integrated circuit package to a second position on the socket;
testing a second portion of the integrated circuit package using the socket during a second period; and
receiving a second response from at least one die of the second portion.

EXAMPLE EMBODIMENT 12. The method of example embodiment 11, wherein at least one of a socket pin of the at least one die of the second portion is depopulated while testing the first portion.

EXAMPLE EMBODIMENT 13. The method of example embodiment 11, wherein rotating the integrated circuit package to the second position causes the at least one die of the first portion to be depopulated while testing the second portion.

EXAMPLE EMBODIMENT 14. The method of example embodiment 11, wherein a die-to-die interface between the at least one die of the first portion and the at least one die of the second portion are power isolated.

EXAMPLE EMBODIMENT 15. The method of example embodiment 11, wherein testing the first portion and testing the second portion comprise sending testing signals to the at least one die of the first portion and the at least one die of the second portion, wherein the testing signals are isolated in the at least one die of the first portion and the at least one die of the second portion.

EXAMPLE EMBODIMENT 16. A tangible, non-transitory, and computer-readable medium, storing instructions thereon that when executed are to cause a processor to:
receive a first response from a die of a first portion of an integrated circuit package from a test of a first portion of socket pins of the integrated circuit package corresponding to a first portion of a die area;
receive a second response from a die of a second portion of the integrated circuit package from a test of a second portion of socket pins of the integrated circuit package corresponding to a second portion of the die area;
analyze the first response from the die of the first portion;
analyze the second response from the die of the second portion; and
determine whether the die of the first portion and the die of the second portion are operating correctly.

EXAMPLE EMBODIMENT 17. The tangible, non-transitory, and computer-readable medium of example embodiment 16, wherein determining whether the die of the first portion and the die of the second portion are operating correctly comprises comparing a first set of data from the first response and a second set of data from the second response to a specific set of data.

EXAMPLE EMBODIMENT 18. The tangible, non-transitory, and computer-readable medium of example embodiment 16, wherein the instructions, when executed, are to cause the processor to:
in response to identifying that the die of the first portion is not operating correctly, powering down the die of the first portion.

EXAMPLE EMBODIMENT 19. The tangible, non-transitory, and computer-readable medium of example embodiment 16, wherein the instructions, when executed, are to cause the processor to transmit an indication indicating that the dies of the integrated circuit package are operating correctly in response to determining that the die of the first portion and the die of the second portion are operating correctly.

EXAMPLE EMBODIMENT 20. The tangible, non-transitory, and computer-readable medium of example embodiment 16, wherein the instructions, when executed, are to cause the processor to:
receive an invalid response from the die of the first portion, the die of the second portion, or any combination thereof; and
individually power down the die of the first portion, the die of the second portion, or any combination thereof based on the invalid response.

What is claimed is:

1. A system comprising:
an integrated circuit package; and
a testing device to:
test a first portion of socket pins of the integrated circuit package corresponding to a first portion of a die area using a socket during a first pass; and
test a second portion of socket pins of the integrated circuit package corresponding to a second portion of the die area using the socket during a second pass.

2. The system of claim 1, wherein the socket is too small for both the first portion and the second portion to be positioned on the socket at the same time.

3. The system of claim 1, wherein testing the second portion comprises rotating the integrated circuit package before positioning the second portion on the socket.

4. The system of claim 3, wherein rotating the integrated circuit package comprises a rotation of 180 degrees.

5. The system of claim 4, wherein the first portion of the integrated circuit package comprises a pin configuration and the rotated second portion also comprises the pin configuration.

6. The system of claim 1, wherein the second portion does not receive any signals from the testing device during the first pass and the first portion does not receive any signals from the testing device during the second pass.

7. The system of claim 1, wherein the first portion comprises at least a first die and the second portion comprises at least a second die of the integrated circuit package.

8. The system of claim 7, wherein the testing device is to test various parameters associated with each die.

9. The system of claim 8, wherein the various parameters comprise timing, voltage levels, current compensation, signal integrity, or any combination thereof.

10. The system of claim 1, wherein the first portion is isolated from the second portion during the test of the first portion and the test of the second portion.

11. A method comprising:
positioning an integrated circuit package in a first position on a socket;
testing a first portion of the integrated circuit package using the socket during a first period;
receiving a first response from at least one die of the first portion;
rotating the integrated circuit package to a second position on the socket;
testing a second portion of the integrated circuit package using the socket during a second period; and
receiving a second response from at least one die of the second portion.

12. The method of claim 11, wherein at least one of a socket pin of the at least one die of the second portion is depopulated while testing the first portion.

13. The method of claim 11, wherein rotating the integrated circuit package to the second position causes the at least one die of the first portion to be depopulated while testing the second portion.

14. The method of claim 11, wherein a die-to-die interface between the at least one die of the first portion and the at least one die of the second portion are power isolated.

15. The method of claim 11, wherein testing the first portion and testing the second portion comprise sending testing signals to the at least one die of the first portion and the at least one die of the second portion, wherein the testing signals are isolated in the at least one die of the first portion and the at least one die of the second portion.

16. A tangible, non-transitory, and computer-readable medium, storing instructions thereon that when executed are to cause a processor to:
receive a first response from a die of a first portion of an integrated circuit package from a test of a first portion of socket pins of the integrated circuit package corresponding to a first portion of a die area;
receive a second response from a die of a second portion of the integrated circuit package from a test of a second portion of socket pins of the integrated circuit package corresponding to a second portion of the die area;
analyze the first response from the die of the first portion;
analyze the second response from the die of the second portion; and
determine whether the die of the first portion and the die of the second portion are operating correctly.

17. The tangible, non-transitory, and computer-readable medium of claim 16, wherein determining whether the die of the first portion and the die of the second portion are operating correctly comprises comparing a first set of data from the first response and a second set of data from the second response to a specific set of data.

18. The tangible, non-transitory, and computer-readable medium of claim 16, wherein the instructions, when executed, are to cause the processor to:
in response to identifying that the die of the first portion is not operating correctly, powering down the die of the first portion.

19. The tangible, non-transitory, and computer-readable medium of claim 16, wherein the instructions, when executed, are to cause the processor to transmit an indication indicating that the dies of the integrated circuit package are operating correctly in response to determining that the die of the first portion and the die of the second portion are operating correctly.

20. The tangible, non-transitory, and computer-readable medium of claim 16, wherein the instructions, when executed, are to cause the processor to:
receive an invalid response from the die of the first portion, the die of the second portion, or any combination thereof; and
individually power down the die of the first portion, the die of the second portion, or any combination thereof based on the invalid response.
